(19) United States
(12) Patent Application Publication
(10) Pub. No.: US 2026/0024717 A1
(43) Pub. Date: Jan. 22, 2026

(54) GRID FOR TRANSMISSION ELECTRON MICROSCOPE

(71) Applicant: FEI COMPANY, Hillsboro, OR (US)

(72) Inventors: Jolet de Ruiter, Eindhoven (NL); Bas Hendriksen, Eindhoven (NL)

(21) Appl. No.: 19/213,466

(22) Filed: May 20, 2025

Related U.S. Application Data
(60) Provisional application No. 63/673,292, filed on Jul. 19, 2024.

(51) Int. Cl. H01J 37/20

(52) U.S. Cl. CPC H01J 37/20

(57) ABSTRACT

A grid for sampling liquid specimens includes a mesh having a plurality of grid bars defining a plurality of openings, and a foil coupled to the mesh. The foil includes a plurality of sections, each section aligned with one of the plurality of openings. At least one of the plurality of sections includes a first portion including a plurality of holes, and a second portion surrounding the first portion and positioned between the first portion and the plurality of grid bars. The second portion is solid.

### CROSS-REFERENCE TO RELATED APPLICATIONS

This application claims priority to U.S. Provisional Application No. 63/673,292, filed Jul. 19, 2024, the entire contents of which are incorporated by reference herein.

### FIELD

The present disclosure relates to a grid for sampling a liquid specimen. The grid may be for sampling a liquid specimen for transmission electron microscopy (TEM) analysis.

### SUMMARY

In one implementation, the disclosure provides a grid for sampling liquid specimens. The grid includes a mesh having a plurality of grid bars defining a plurality of openings. The grid also includes a foil coupled to the mesh. The foil includes a plurality of sections, each section aligned with one of the plurality of openings. At least one of the plurality of sections includes a first portion including a plurality of holes, and a second portion surrounding the first portion and positioned between the first portion and the plurality of grid bars. The second portion is solid.

In another implementation, the disclosure provides a grid for sampling liquid specimens. The grid includes a mesh having a plurality of grid bars defining a plurality of openings. At least one of the plurality of openings has a first dimension measured between opposing grid bars that define the at least one of the plurality of openings. The grid also includes a foil coupled to the mesh and defining a plurality of holes aligned with at least some of the plurality of openings. A subset of the plurality of holes that is aligned with the at least one of the plurality of openings has a second dimension measured between opposing sides of the subset. The subset of the plurality of holes is the only holes within the at least one of the plurality of openings. A ratio of the second dimension to the first dimension is less than 1.

In another implementation, the disclosure provides a system for sampling liquid specimens. The system includes a grid having a mesh having a plurality of grid bars defining a plurality of openings. At least one of the plurality of openings has an opening dimension measured between opposing grid bars that define the at least one of the plurality of openings. The grid also has a foil coupled to the mesh and defining a plurality of holes. A subset of the plurality of holes is aligned with one of the plurality of openings and has a subset dimension measured between opposing sides of the subset. The system also includes an applicator for applying a droplet of a liquid specimen on the grid. The droplet has a hypothetical equilibrium dimension when applied to a foil that is continuously holey. The subset dimension is less than the opening dimension and the hypothetical equilibrium dimension.

Other aspects of the disclosure will become apparent by consideration of the detailed description and accompanying drawings.

### BRIEF DESCRIPTION OF THE DRAWINGS

FIG. 1 is a perspective view of a grid for sampling a liquid specimen.

FIG. 2 is a cross-sectional, schematic view of a portion of the grid of FIG. 1, illustrating an applicator applying a droplet of the liquid specimen to the grid.

FIG. 3A is a cross-sectional, schematic view of the portion of the grid of FIG. 2, illustrating the droplet of the liquid specimen applied to the grid.

FIG. 3B is a cross-sectional, schematic view of the portion of the grid of FIG. 2, illustrating the droplet of the liquid specimen after spreading.

FIG. 3C is a cross-sectional, schematic view of the portion of the grid of FIG. 2, illustrating the droplet of the liquid specimen after evaporation.

FIG. 3D is a cross-sectional, schematic view of a portion of another grid for sampling a liquid specimen, illustrating a droplet of the liquid specimen applied to the grid.

FIG. 4 is a top schematic view of a portion of the grid of FIG. 1 with a droplet applied to the grid.

FIG. 5 is a schematic diagram of an electronic control system and a microcontroller.

FIG. 6 is a flowchart depicting a method of sampling a liquid specimen using the grid of FIG. 1.

### DETAILED DESCRIPTION

Before any implementations of the disclosure are explained in detail, it is to be understood that the disclosure is not limited in its application to the details of construction and the arrangement of components set forth in the following description or illustrated in the following drawings. The disclosure is capable of other implementations and of being practiced or of being carried out in various ways.

The present disclosure relates to a sample preparation system 110 for sampling a liquid specimen 114. The sample preparation system 110 is configured to prepare the liquid specimen 114 for analysis by a charged particle microscope (e.g., a transmission electron microscope [TEM]). The illustrated application is only one example, and the sample preparation system 110 may be utilized in any sampling application, especially when sampling a liquid specimen 114.

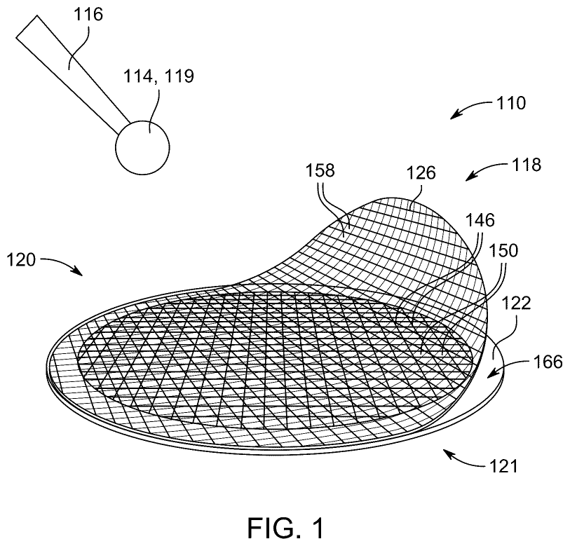

As illustrated in FIG. 1, the sample preparation system 110 includes an applicator 116 for applying the liquid specimen 114 and a grid 118 configured to receive and hold the liquid specimen 114. The applicator 116 is configured to place a droplet 119 of the liquid specimen 114 onto the grid 118. In the present embodiment, the applicator 116 is an inkjet printer, however, in other embodiments, a different device may be used to place the liquid specimen 114 onto the grid 118 (e.g., a pipette, syringe, etc.). The applicator 116 is configured to place the droplets 119 onto a first side 120 of the grid 118. In alternate embodiments, the applicator 116 may place the droplets 119 onto a second side 121 of the grid 118. The droplets 119 may have volumes ranging from 1 to 100 picolitres. In some embodiments, the droplets may have volumes ranging from 15 to 30 picolitres. In the present embodiment, each droplet 119 has a volume of approximately 22 picolitres. In alternate embodiments, the droplets 119 may have other volumes. In some embodiments, multiple droplets 119 may be placed onto the grid 118, and each droplet 119 may have a different volume.

The illustrated grid 118 includes a mesh 122 and a foil 126. The foil 126 defines the first side 120 of the grid 118. The mesh 122 defines the second side 121 of the grid 118. The mesh 122 and the foil 126 are substantially the same shape and size. In the illustrated embodiment, both the mesh 122 and the foil 126 are circular in shape. In alternate embodiments, the mesh 122 and the foil 126 may be a different shape (e.g., square, rectangular, trapezoidal, etc.), or the mesh 122 may have a different shape from the foil 126 (e.g., the mesh 122 may be circular and the foil 126 may be square).

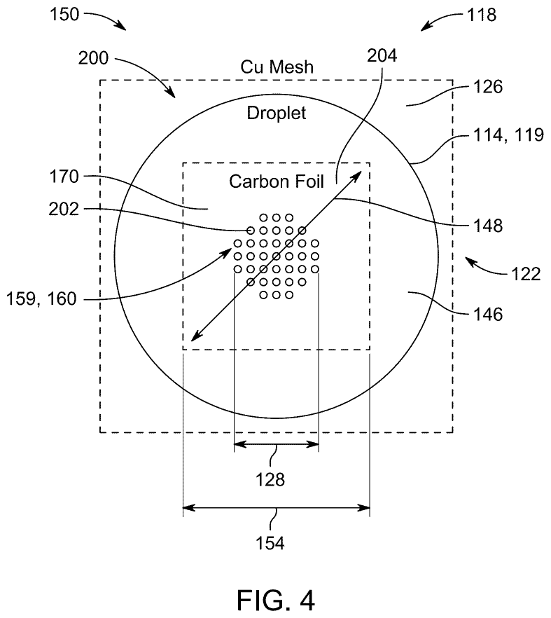

The mesh 122 includes a plurality of grid bars 146 defining a plurality of openings 150. The openings 150 may be further understood as an area defined by the grid bars 146 on both the first side 120 and the second side 121 of the grid 118. Accordingly, the openings 150 may be on the first side 120 or the second side 121. As shown in FIG. 4, each of the illustrated openings 150 is generally square in shape. In alternate embodiments, each of the plurality of openings 150 may have other shapes (e.g., circular, rectangular, hexagonal, oblong, etc.). Each of the plurality of openings 150 has a first dimension 154, or opening dimension, measured between opposing grid bars 146. The first dimension 154 is a minimum dimension between the opposing grid bars 146. For example, the illustrated opening 150 is a square, and the first dimension 154 is a width measured perpendicularly between the opposing grid bars 146. In embodiments where the opening 150 is, for example, a circle, the first dimension 154 may be a diameter of the circle. The first dimension 154 may be between 50 and 100 microns. In the illustrated embodiment, the first dimension is approximately 60 microns. In other embodiments, the first dimension 154 may be less than 50 microns or greater than 100 microns. Each of the plurality of grid bars 146 has a width 156. In the present embodiment, the width 156 is approximately 25 micrometers. In other embodiments, the grid bars 146 may have other widths in a range from 10 to 200 micrometers.

In the present embodiment, the foil 126 may be a plastic film. Amorphous carbon may be deposited onto the plastic film after which the plastic film may be dissolved. Alternatively, the plastic film may remain along with the amorphous carbon. In some embodiments, the mesh 122 may be built upon the foil 126 to form a one-piece mesh-foil structure and the foil 126 may be made of a metal such as gold. In other embodiments, the foil 126 may be made of a different material (e.g., plastic, glass, etc.).

In the present embodiment, the mesh 122 is hydrophilic and the foil 126 is hydrophilic. In alternate embodiments, the mesh 122 may not be hydrophilic, or the foil 126 may not be hydrophilic, or both the mesh 122 and the foil 126 may not be hydrophilic. The mesh 122 has a mesh thickness of 15 micrometers. The foil 126 has a foil thickness of 10 nanometers. In alternate embodiments, the mesh 122 and the foil 126 may have other thicknesses. For example, the mesh 122 may have a nominal mesh thickness in a range from 5 to 35 micrometers. The foil 126 may have a nominal foil thickness in a range from 5 to 50 nanometers.

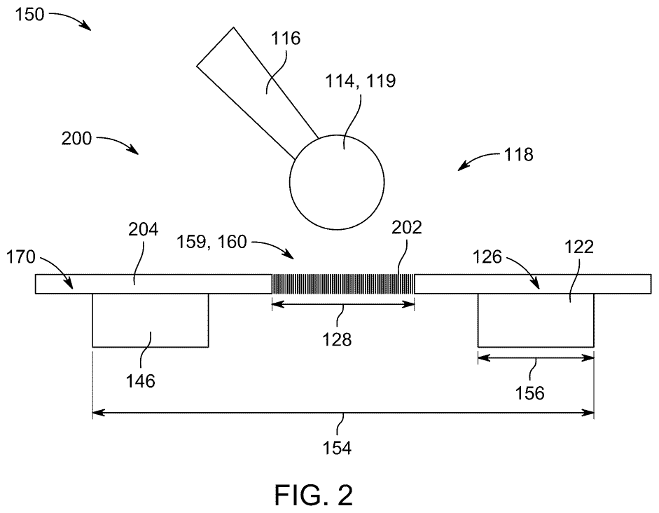

As shown in FIGS. 2 and 4, the foil 126 includes a plurality of sections 200. Each section 200 aligns with one of the plurality of openings 150. In the illustrated embodiment, each section 200 includes a first portion 202, or area, and a second portion 204, or area, surrounding the first portion 202. As explained below, the first portion 202 is perforated or holey, while the second portion 204 is solid. In other embodiments, only some of the sections 200 may be divided into first portions 202 and second portions 204. In such embodiments, some of the sections 200 may be completely perforated or holey, and/or some of the sections 200 may be completely solid.

The foil 126 further includes a plurality of holes 158. The holes 158 are arranged in the first portion 202 of each section 200. In the illustrated embodiment, each of the plurality of holes 158 is generally circular. In alternate embodiments, the plurality of holes 158 may be different shapes (e.g., square, triangular, oblong, etc.). Subsets 159 of the plurality of holes 158 are arranged in clusters 160. A cluster 160 is a collection of the plurality of holes 158 that is spaced from a similar collection of holes 158. Each cluster 160 is positioned in a corresponding first portion 202 of one of the sections 200. As such, each cluster 160 generally defines the corresponding first portion 202. The plurality of holes 158 is arranged in a continuous pattern on the first portion 202. The clusters 160 may be arranged in circular patterns, square patterns, hexagonal patterns, octagonal patterns, triangular patterns, oblong patterns, irregular patterns, and the like. Each cluster 160 may be arranged in a similar pattern, or each cluster 160 may be arranged in a different pattern from other clusters 160. The continuous pattern formed by each cluster 160 extends over an entirety of the corresponding first portion 202.

The second portion 204 of each section 200 is positioned between the first portion 202 and the corresponding grid bars 146. In some embodiments, the second portion 204 of each section 200 may also extend over the grid bars 146. In such embodiments, the second portion 204 of one section 200 may connect or be continuous with the second portion 204 of an adjacent section 200. In the present embodiment, each second portion 204 is solid. That is, in contrast to the first portion 202, the second portion 204 is free of and does not include holes, such as the holes 158. However, the second portions 204 may include pinning features, as explained below. In the illustrated embodiment, each second portion 204 is larger than the corresponding first portion 202. In other words, each second portion 204 has a surface area that is greater than a surface area of the first portion 204. In other embodiments, the surface areas of the first and second portions 202, 204 may be generally equal, or the surface area of the first portion 202 may be greater than the surface area of the second portion 204. In still other embodiments, the size (e.g., surface area) of the first portion 202 to the second portion 204 may vary from section 200 to section 200.

As shown in FIG. 1, a back portion 166 of the mesh 122 corresponds with and is at least partially in contact with the foil 126. Accordingly, the subset 159 of the plurality of holes 158 on the foil 126 is configured to align with one of the plurality of openings 150. Each hole 158 of the subset 159 is spaced apart from the grid bars 146. In the present embodiment, none of the holes 158 of the subset 159 partially overlaps the plurality of grid bars 146 of the corresponding opening 150. Rather, the solid, second portions 204 of the foil 126 are in contact with the grid bars 146. Furthermore, in the present embodiment, the subset 159 constitutes the only holes of the corresponding opening 150. That is, no other holes are positioned within a perimeter of the opening 150. In the present embodiment, a subset 159 of the plurality of holes 158 is aligned with each of the plurality of openings 150. In alternate embodiments, only some of the plurality of openings 150 may correspond to subsets 159 of the plurality of holes 158.

Referring to FIGS. 2-4, the subset 159 has a second dimension 128, or subset dimension, measured between opposing sides of the subset 159. The second dimension 128 may be measured in the same direction as, or parallel to, the first dimension 154. In particular, the second dimension 128 is a maximum dimension between opposing sides of the subset 159 measured parallel to the first dimension 154. The second dimension 128 is less than the first dimension 154. In some embodiments, the second dimension 128 may be less than 42 microns. In the illustrated embodiment, the second dimension 128 may be about 35 microns. In other embodiments, the second dimension 128 may be less than 35 microns or greater than 42 microns. In the present embodiment, a ratio of the second dimension 128 to the first dimension 154 is less than 1. In some embodiments, the ratio of the second dimension 128 to the first dimension 154 may be less than 0.75. In some embodiments, the ratio of the second dimension 128 to the first dimension 154 may be less than 0.6. In other embodiments, the ratio of the second dimension 128 to the first dimension 154 may range from 0.25 to 1.0. In still other embodiments, depending on the wettability of the foil 126 and the size of the droplet 119, the ratio of the second dimension 128 to the first dimension 154 may be greater than 0.75.

Each droplet 119 is configured to be placed in, or applied to, one of the plurality of openings 150. Each liquid specimen 114 is spaced apart to allow for multiple different liquid specimens 114 or multiple similar liquid specimens 114 to be sampled on a single grid 118. In response to the droplet 119 being applied to the respective opening 150, the droplet 119 is configured to initially contact the first portion 202 of the foil 126 and spread over the second portion 204 until the droplet 119 reaches an equilibrium state in which the droplet 119 stops spreading. In other words, applying the droplet 119 to the foil 126 within one of the openings 150 includes spreading the droplet 119 across the second dimension 128 without being stopped by pinning forces caused by the plurality of holes 158. The droplet 119 therefore spreads across the one of the plurality of openings 150 such that the droplet 119 reaches the equilibrium state.

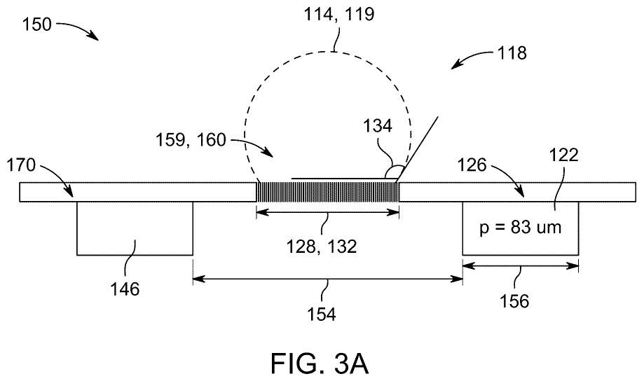

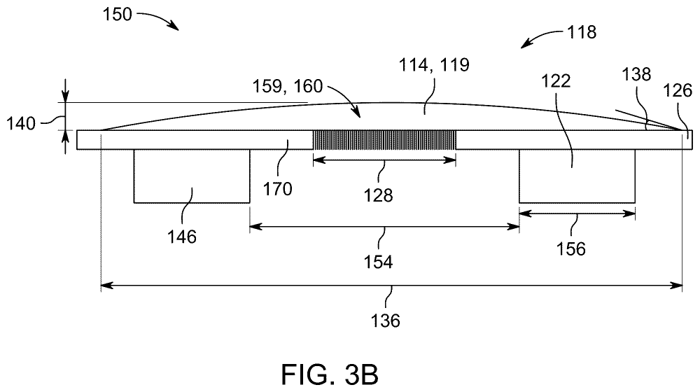

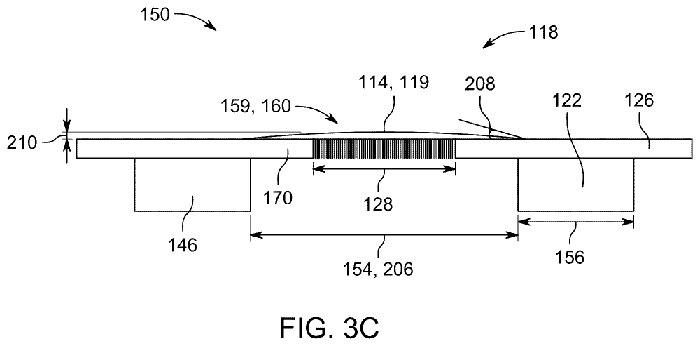

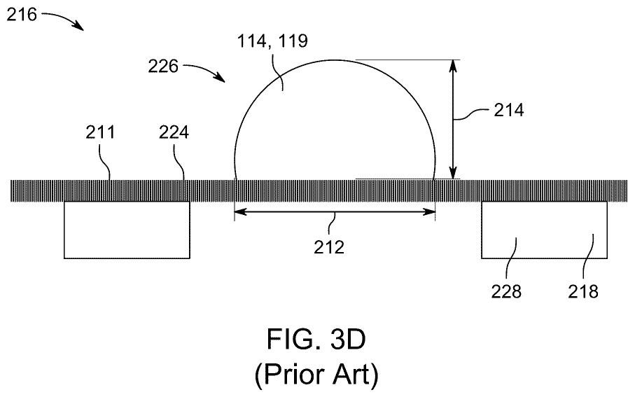

As shown in FIG. 3A, the droplet 119 has a first state, which is defined by the droplet 119 having a first droplet footprint diameter 132 equal to the second dimension 128. The droplet 119 in the first state has the first droplet footprint diameter 132 and a first grid contact angle 134. The first droplet footprint diameter 132 is defined by the diameter of the droplet 119 in contact with the grid 118. In the present embodiment, the first droplet footprint diameter 132 is equal to the second dimension 128 of the subset 159 of the plurality of holes 158. In other embodiments, the first droplet footprint diameter 132 may be larger than the second dimension 128 of the subset 159 of the plurality of holes 158. In some embodiments, the first droplet footprint diameter 132 may be greater than 35 microns. In other embodiments, the first droplet footprint diameter 132 may be greater than 40 microns. In still other embodiments, the first droplet footprint diameter 132 may be between 20 microns and 60 microns. In the illustrated embodiment, the first drop footprint diameter 132 is about 42 microns. The first grid contact angle 134 is defined by an angle created between the surface of the grid 118 and an outermost surface of the droplet 119. It should be understood that all contact angles described herein are apparent contact angles. In some embodiments, the first grid contact angle 134 may be between 100 and 160 degrees. In the illustrated embodiment, the first grid contact angle is about 125 degrees.

As shown in FIG. 3B, the droplet 119 has a maximum spread state, which occurs after the first state. Due to wetting forces, after the droplet 119 is applied to the grid 118, the droplet 119 spreads within or even past the opening 150 until the droplet 119 reaches an equilibrium. While the droplet 119 is spreading, the contact angle created between the surface of the grid 118 and the outermost surface of the droplet 119 changes until the droplet 119 reaches a maximum spread contact angle 138. In other words, the droplet 119 spreads while the contact angle is greater than the maximum spread contact angle 138, and the droplet 119 stops spreading when the contact angle is less than or equal to the maximum spread contact angle 138. In the present embodiment, the maximum spread state is also defined by the droplet 119 being spread onto and/or extending beyond the grid bars 146 and thus filling the entire opening 150. The grid bars 146 are further configured to restrict the droplet 119 from substantially receding after the droplet 119 has reached the maximum spread state. Receding may occur, for example, upon volume decrease due to evaporation or blotting. The droplet 119 in the maximum spread state has a maximum spread dimension 136, the maximum spread contact angle 138, and a maximum spread thickness 140. In some embodiments, the maximum spread dimension 136 may be at least 90 microns. In other embodiments, the maximum spread dimension 136 may be 60 to 200 microns. In the illustrated embodiment, the maximum spread dimension 136 is about 100 microns. The maximum spread contact angle 138 is defined by an angle created between the surface of the grid 118 and an outermost portion of the pinned droplet 119. The maximum spread contact angle 138 is less than the first grid contact angle 134. In some embodiments, the maximum spread contact angle 138 may be 5 to 45 degrees. In the illustrated embodiment, the maximum spread contact angle 138 is about 10 degrees. The maximum spread thickness 140 is a thickness of the droplet 119 after spreading, measured perpendicular to the foil 126 at the thickest part of the droplet 119. In some embodiments, the maximum spread thickness 140 may range from 1 to 10 microns. In other embodiments, the maximum spread thickness 140 may be less than 8 microns. In the illustrated embodiment, the maximum spread thickness 140 is about 6 microns.

As shown in FIG. 3C, the droplet 119 further has an evaporated state, or shrunk state, which occurs after the maximum spread state. In the present embodiment, the shrunk state is also defined by the droplet 119 experiencing volume reduction through evaporation or blotting after being pinned by the grid bars 146. The droplet 119 in the shrunk state has an evaporated dimension 206, an evaporated contact angle 208, and an evaporated thickness 210. The evaporated dimension 206 is greater than or equal to the first droplet footprint diameter 132 and less than the maximum spread dimension 136. In some embodiments, the droplet 119 may completely or near completely fill the opening 150 when in the shrunk state. In such embodiments, the evaporated dimension 206 may be substantially equal to the first dimension 154 of the opening 150. In other embodiments, the droplet 119 may not completely fill the opening 150. In such embodiments, the evaporated dimension 206 may be less than the first dimension 154 of the opening 150. In either scenario, the evaporated dimension 206 may be a diameter of the spread droplet 119. Alternatively, if the droplet 119 completely fills the opening 150, the evaporated dimension 206 may be a width of the spread droplet 119 (depending on the shape of the opening 150). In some embodiments, the evaporated dimension 206 may be at least 60 microns. In other embodiments, the evaporated dimension 206 may be 60 to 100 microns. In the illustrated embodiment, the evaporated dimension 206 is about 70 microns. The evaporated contact angle 208 is defined by an angle created between the surface of the grid 118 and an outermost portion of the pinned droplet 119. The evaporated contact angle 208 is less than the maximum spread contact angle 138. In some embodiments, the evaporated contact angle 208 may be 1 to 10 degrees. In the illustrated embodiment, the evaporated contact angle 208 is about 5 degrees. The evaporated thickness 210 is a thickness of the droplet 119 after evaporation, measured perpendicular to the foil 126 at the thickest part of the droplet 119. In some embodiments, the evaporated thickness 210 may range from 1 to 5 microns. In other embodiments, the evaporated thickness 210 may be less than 3 microns. In the illustrated embodiment, the evaporated thickness 210 is about 2 microns.

In other embodiments, the droplet 119 may not be pinned by the grid bars 146. Instead, the droplet 119 may be pinned to a pinning feature on the grid 118. The pinning feature may be an uneven surface formed or positioned on the foil 126. For example, the pinning feature may include a ridge, bump, recess, aperture, or the like formed on the foil 126. In some embodiments, the pinning feature may include a series of ridges, bumps, recesses, or apertures or the like formed on the foil 126. The pinning feature may be arranged as a perimeter or concentric ring formed around but separated from the subset 159 of the plurality of holes 158 by part of the solid portion 170 of the foil 126. For example, the pinning feature may be formed or positioned on the second portion 204 of a corresponding section 200. The pinning feature, thereby, may be positioned inboard of the grid bars 146 and outboard of the plurality of holes 158. The pinning feature may further be positioned outboard of the grid bars 146 in embodiments where a neighboring square does not include a plurality of holes 158. The pinning feature may further be positioned on top of the grid bars 146.

The size of the droplet 119 and the size of the subset 159 of the plurality of holes 158 are selected to encourage spreading of the droplet along the grid 118. FIG. 3D illustrates another grid 216 including a mesh 218 having a plurality of grid bars 228 and a foil 211 coupled to the mesh 218. In contrast to the foil 126 described above, the foil 211 is continuously holey. That is, the foil 211 does not include portions with holes surrounded by portions without holes (i.e., that are solid). Instead, the foil 211 defines a plurality of holes 224 that are arranged continuously along an entirety of the foil 211, or at least continuously within an entirety of an opening 226 defined by the grid bars 228.

As shown in FIG. 3D, when the droplet 119 is applied to the foil 211 that is continuously holey, the droplet 119 may pin to the holes 224 and stop spreading. In this state, the droplet 119 has a hypothetical equilibrium dimension 212 and a hypothetical maximum spread thickness 214. As used herein, the hypothetical equilibrium dimension 212 is the diameter of the droplet 119 on the foil 211 after the droplet 119 is pinned to the holes 224 and no longer spreading, but before evaporation and/or blotting. The hypothetical maximum spread thickness 214 is a thickness of the droplet 119 when in this state, measured perpendicular to the foil 211 at the thickest part of the droplet 119. In some embodiments, the hypothetical equilibrium dimension 212 may be about 40 microns, and the hypothetic maximum spread thickness 214 may be about 24 microns. These dimensions are considered “hypothetical” because the droplet 119 is not actually applied to the foil 211 that is continuously holey. Rather, the droplet 119 is applied to the foil 126 shown in FIGS. 3A-3C that includes subsets 159 of the holes 158.

The subset dimension 128 (FIGS. 3A-3C) of the holes 158 of the foil 126 is selected to be less than this hypothetical equilibrium dimension 212 of the droplet 119. As such, the droplet 119 does not pin on the holes 158. Instead, the droplet 119 spreads past the holes 158 onto the solid, second portion 204 of the foil 126. As noted above with respect to FIG. 3B, the opening dimension 154 between the opposing grid bars 146 is also less than the maximum spread dimension 136 of the droplet 119 such that the droplet 119 can spread beyond the grid bars 146. The opening dimension 154 is also less than a critical dimension 148 of the droplet 119. The critical dimension 148 is defined by the largest dimension measured across the opening 150. Accordingly, in the present embodiment, because the opening 150 is a square shape, the critical dimension 148 is defined by the diagonal distance between opposite corners of the opening 150. In addition, as noted above with respect to FIG. 3C, the opening dimension 154 between the opposing grid bars 146 may also be less than the evaporated dimension 206 of the droplet 119 such that the droplet 119 can pin to the grid bars 146.

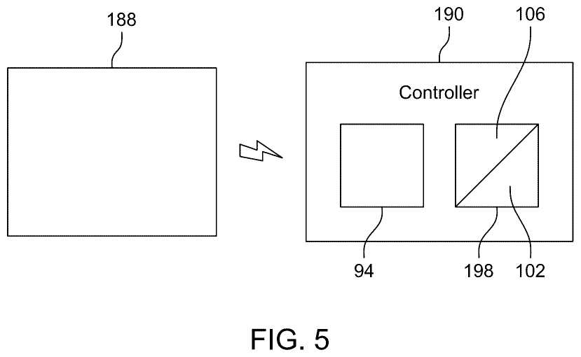

In some embodiments, the applicator 116 includes a micromanipulator 188 to precisely operate the applicator 116. FIG. 5 illustrates the sample preparation system 110 including the micromanipulator 188. In some embodiments, the micromanipulator 188 is configured to detect the location of the holes 158 and the location of the grid bars 146. The micromanipulator 188 then positions the applicator 116 such that the applicator 116 aligns with one of the openings 150 to precisely deposit the droplet 119 onto the opening 150. This allows for multiple similar or different liquid specimens 114 to be deposited on the grid 118. The illustrated sample preparation system 110 also includes an electronic controller 190 configured to automatically or semi-automatically control the micromanipulator 188. The controller 190 may include a programmable processor 94 (e.g., a microprocessor, a microcontroller, or another suitable programmable device) and a memory 198 such as a non-transitory memory. The memory 198 may include, for example, a program storage area 102 and a data storage area 106. The program storage area 102 and the data storage area 106 can include combinations of different types of memory 198, such as read only memory (“ROM”), random access memory (“RAM”) (e.g., dynamic RAM [“DRAM”], synchronous DRAM [“SDRAM”], etc.), electrically erasable programmable read-only memory (“EEPROM”), flash memory, a hard disk, an SD card, or other suitable magnetic, optical, physical, electronic memory devices, or other data structures. Programming may be coded or learned.

As one example, the electronic controller 190 may be configured to control rotation and movement of the micromanipulator 188. The electronic controller 190 may also be configured to control the position of the micromanipulator 188 in 3-dimensional space, e.g., to move or rotate the micromanipulator 188 to align the mesh 122 with the foil 126, which may include moving or in the X-direction, the Y-direction, and/or the Z-direction, in any combination or orientation.

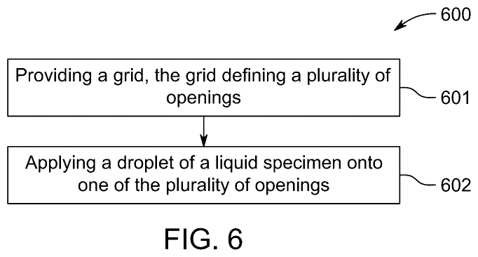

FIG. 6 is a flowchart depicting a method 600 of sampling a liquid specimen 114 for analysis in a charged particle microscope (e.g., a transmission electron microscope, scanning electron microscope, etc.). Although the method includes particular steps, not all of the steps need to be performed or need to be performed in the order presented. In some embodiments, the method may include additional steps. At least some of the method may be carried out by the electronic controller 190.

At step 601, a user provides the grid 118. The grid 118 includes the mesh 122 and the foil 126. The mesh 122 includes the plurality of grid bars 146 defining the plurality of openings 150. The foil 126 is coupled to the mesh 122 and defines the plurality of holes 158. The subset 159 of the plurality of holes 158 is aligned with one of the plurality of openings 150 and has the subset dimension 128 measured between opposing sides of the subset 159. The subset 159 of the plurality of holes 158 defines the only holes within the one of the plurality of openings 150. Step 601 may also include a subset of the plurality of holes 158 aligned with each of the plurality of openings 150, where each subset 159 of the plurality of holes 158 has the subset dimension 128 measured between opposing sides of the corresponding subset 159. The subset 159 of the plurality of holes 158 defines the only holes within the corresponding opening 150.

At step 602, the droplet 119 is applied onto the foil 126 over one of the plurality of openings 150. The droplet 119 is applied using the applicator 116. Step 602 may further include using an inkjet printer to apply the droplet 119. In some embodiments, different devices may be used to place the liquid specimen 114 onto the grid 118 (e.g., a pipette, syringe, etc.). Step 602 may further include applying, using the applicator 116, the droplet 119 of the liquid specimen 114 onto each of the plurality of openings 150 of the grid 118, each droplet 119 having the pinned droplet footprint dimension 136 that is larger than the subset dimension 128. Step 602 may further include spreading the droplet 119 of the liquid specimen 114 across the one of the plurality of openings 150 such that the droplet 119 pins to the plurality of grid bars 146 upon volume reduction. Further method steps and intermediary method steps are apparent from the description above and the operational description below.

In operation, the grid 118 is first provided. Next, the applicator 116 applies the droplet 119 of the liquid specimen 114 to one of the plurality of openings 150 of the grid 118. The droplet 119 then spreads within the opening 150 due to wetting forces until the droplet 119 reaches the maximum spread contact angle 138 and the grid bars 146 pin the liquid specimen 114. The liquid specimen 114 may then be vitrified to transform the liquid specimen 114 to a frozen state in preparation for analysis. The grid 118 may then be analyzed by the microscope (e.g., TEM). It should be noted that other preparation techniques may be used.

Applying a droplet 119 onto a grid 118 having a first portion 202 including a plurality of holes 158 and a second portion 204 that is solid encourages spreading of the droplet 119 when the droplet 119 is placed on the grid 118. For example, the droplet 119 can spread over a much larger area and into a thinner deposit than is typically achieved when applied to a continuously holey foil 211, as shown in FIG. 3D. In those situations, the droplet 119 may become pinned by the holes 158 themselves, which limits spreading of the droplet 119. Due to the limited spreading, the droplet 119 would have a relatively thick hypothetical maximum spread thickness 214 in comparison to the maximum spread thickness 140, which requires further blotting or evaporation to obtain a thickness suitable for cryo-EM. These processes take time and could potentially affect sample composition or lead to sample loss.

Various features and advantages of the invention are set forth in the following claims.

What is claimed is:

1. A grid for sampling liquid specimens, the grid comprising:
a mesh including a plurality of grid bars defining a plurality of openings; and
a foil coupled to the mesh, the foil including a plurality of sections, each section aligned with one of the plurality of openings, wherein at least one of the plurality of sections includes
a first portion having a plurality of holes, and
a second portion surrounding the first portion and positioned between the first portion and the plurality of grid bars, the second portion being solid.

2. The grid of claim 1, wherein each of the plurality of sections includes
a first portion having a plurality of holes, and
a second portion surrounding the first portion and positioned between the first portion and the plurality of grid bars, the second portion being solid.

3. The grid of claim 1, wherein each of the plurality of openings has a first dimension measured between opposing grid bars that define a corresponding opening of the plurality of openings, wherein the plurality of holes of the first portion is arranged in a cluster having a second dimension measured between opposing sides of the cluster, and wherein the second dimension is less than the first dimension.

4. The grid of claim 3, wherein the first dimension is approximately 60 microns.

5. The grid of claim 3, wherein the second dimension is less than 42 microns.

6. The grid of claim 1, wherein the plurality of holes is arranged in a continuous pattern on the first portion.

7. The grid of claim 6, wherein the continuous pattern of the plurality of holes extends over an entirety of the first portion.

8. The grid of claim 1, wherein the second portion has a surface area that is greater than a surface area of the first portion.

9. A grid for sampling liquid specimens, the grid comprising:
a mesh including a plurality of grid bars defining a plurality of openings, at least one of the plurality of openings having a first dimension measured between opposing grid bars that define the at least one of the plurality of openings; and
a foil coupled to the mesh and defining a plurality of holes aligned with at least some of the plurality of openings,
wherein a subset of the plurality of holes that is aligned with the at least one of the plurality of openings has a second dimension measured between opposing sides of the subset, the subset of the plurality of holes being the only holes within the at least one of the plurality of openings, and
wherein a ratio of the second dimension to the first dimension is less than 1.

10. The grid of claim 9, wherein the ratio is less than 0.75.

11. The grid of claim 10, wherein the ratio is less than 0.6.

12. The grid of claim 9, wherein the second dimension is less than 42 microns.

13. The grid of claim 9, wherein the first dimension is approximately 60 microns.

14. The grid of claim 9, wherein a subset of the plurality of holes is aligned with each of the plurality of openings, wherein each subset of the plurality of holes has the second dimension measured between opposing sides of the subset, and wherein each subset of the plurality of holes is the only holes within a corresponding opening of the plurality of openings.

15. A system for sampling liquid specimens, the system comprising:
a grid including:
a mesh having a plurality of grid bars defining a plurality of openings, at least one of the plurality of openings having an opening dimension measured between opposing grid bars that define the at least one of the plurality of openings,
a foil coupled to the mesh and defining a plurality of holes, wherein a subset of the plurality of holes is aligned with one of the plurality of openings and has a subset dimension measured between opposing sides of the subset; and
an applicator for applying a droplet of a liquid specimen on the grid, the droplet having a hypothetical equilibrium dimension when applied to a foil that is continuously holey,
wherein the subset dimension is less than the opening dimension and the hypothetical equilibrium dimension.

16. The system of claim 15, wherein the opening dimension is less than a maximum spread dimension of the droplet.

17. The system of claim 16, wherein the opening dimension is also less than an evaporated dimension of the droplet.

18. The system of claim 15, wherein the applicator includes an inkjet printer.

19. The system of claim 15, wherein the subset dimension is less than 42 microns.

20. The system of claim 15, wherein the opening dimension is approximately 60 microns.
